(19) United States
(12) Patent Application Publication
(10) Pub. No.: US 2026/0223658 A1
(43) Pub. Date: Jul. 30, 2026

(54) INTEGRATED CIRCUIT DEVICES INCLUDING A CONDUCTIVE VIA AND METHODS OF FORMING THE SAME

(71) Applicant: Samsung Electronics Co., Ltd., Suwon-si (KR)

(72) Inventors: Joongsuk Oh, Watervliet, NY (US); Johnsoo Kim, Clifton Park, NY (US); Gwangsik Kim, Clifton Park, NY (US); Kang-ill Seo, Springfield, VA (US)

(21) Appl. No.: 19/259,776

(22) Filed: Jul. 3, 2025

Related U.S. Application Data
(60) Provisional application No. 63/750,957, filed on Jan. 29, 2025.

(51) Int. Cl. H01L 23/522; H01L 21/3213; H01L 21/768; H01L 23/528; H01L 23/532

(52) U.S. Cl. CPC H10W 20/42; H10P 50/71; H10W 20/072; H10W 20/43; H10W 20/435; H10W 20/4441; H10W 20/46; H10W 20/498

(57) ABSTRACT

An integrated circuit device includes a substrate, a metal via on the substrate, and a metal pattern between the metal via and the substrate in a first direction that is perpendicular to an upper surface of the substrate. The integrated circuit device further includes a first insulating pattern that overlaps the metal pattern and the metal via in a second direction that is parallel with the upper surface of the substrate. The integrated circuit device also includes a second insulating pattern that overlaps the metal via in the second direction and overlaps the metal pattern in the first direction.

### CROSS-REFERENCE TO RELATED APPLICATIONS

This application claims priority to U.S. Provisional Application Ser. No. 63/750,957 entitled INTEGRATED CIRCUIT DEVICES WITH TOP VIA SCHEME AND METHODS OF MANUFACTURING THE SAME, filed in the USPTO on Jan. 29, 2025, the disclosure of which is hereby incorporated by reference herein in its entirety.

### TECHNICAL FIELD

The present disclosure generally relates to the field of electronics and, more particularly, to integrated circuit devices.

Various back end of line (BEOL) structures of an integrated circuit device with different configurations and materials have been suggested to reduce resistance and process complexity thereof so as to improve the performance (e.g., the operation speed) and the production yield of the integrated circuit device.

### SUMMARY

An aspect of the present disclosure is to provide integrated circuit devices with metal vias and metal patterns formed by metal via embedded (hard) mask process, enabling a lower aspect ratio for the metal patterns, improved uniformities of the metal vias and the metal patterns, and ease of metal via revealing. An aspect of the present disclosure is to provide integrated circuit devices with BEOL structures formed by metal via first scheme (metal pattern last scheme). However, it will be understood that the embodiments, goals, and benefits of the present disclosure are not limited to the descriptions above.

According to some embodiments, an integrated circuit device may include a substrate; a metal via on the substrate; a metal pattern between the metal via and the substrate in a first direction that is perpendicular to an upper surface of the substrate; a first insulating pattern that overlaps the metal pattern and the metal via in a second direction, wherein the second direction is parallel with the upper surface of the substrate; and a second insulating pattern that overlaps the metal via in the second direction and overlaps the metal pattern in the first direction.

According to some embodiments, an integrated circuit device may include a substrate; monolithic metal structures that comprise metal vias on the substrate and metal patterns between the metal vias and the substrate in a first direction that is perpendicular to an upper surface of the substrate; first insulating patterns that extend around the metal patterns and the metal vias; and second insulating patterns that extend around the metal vias, wherein the second insulating patterns overlap the metal patterns in the first direction.

According to some embodiments, a method of forming an integrated circuit devices may include forming a stack structure that comprises a first etch stop layer, a metal layer, a second etch stop layer, and a first mask layer on a substrate; forming a first mask pattern and a second etch stop pattern by patterning the first mask layer and the second etch stop layer, respectively; forming a metal via by removing a portion of the metal layer through the first mask pattern and the second etch stop pattern; removing the first mask pattern; forming a second mask layer on the metal via; forming a third mask pattern on the second mask layer, wherein the third mask pattern overlaps the metal via in a first direction that is perpendicular to an upper surface of the substrate; forming a second mask pattern by removing a portion of the second mask layer through the third mask pattern; and forming a metal pattern by removing a portion of the metal layer through the second mask pattern, wherein a side surface of the metal pattern is non-coplanar with a side surface of the metal via.

### BRIEF DESCRIPTION OF THE DRAWINGS

FIG. 1A is a diagram illustrating an integrated circuit device according to some embodiments.

FIG. 1B is a layout of a BEOL structure of an integrated circuit device according to some embodiments.

FIG. 1C is a cross-sectional view taken along the line A-A′ in FIG. 1B according to some embodiments.

FIG. 2 is a cross-sectional view taken along the line A-A′ in FIG. 1B according to some embodiments.

FIG. 3 is a flow chart of methods of forming an integrated circuit device according to some embodiments.

FIGS. 4 through 15 are cross-sectional views, taken along the line A-A′ in FIG. 1B, illustrating methods of forming an integrated circuit device in FIG. 1C or FIG. 2 according to some embodiments. FIG. 4 is a cross-sectional view of an intermediate process, including forming a stack structure.

FIG. 5 is a cross-sectional view of an intermediate process, including forming a first mask pattern, a second etch stop pattern, and a metal via.

FIG. 6 is a cross-sectional view of an intermediate process, including removing the first mask pattern.

FIG. 7 is a cross-sectional view of an intermediate process, including forming a second mask layer.

FIG. 8 is a cross-sectional view of an intermediate process, including removing a portion of the second mask layer.

FIG. 9 is a cross-sectional view of an intermediate process, including forming a third mask pattern.

FIG. 10 is a cross-sectional view of an intermediate process, including forming a second mask pattern.

FIG. 11 is a cross-sectional view of an intermediate process, including forming a (lower) metal pattern.

FIG. 12 is a cross-sectional view of an intermediate process, including forming a first etch stop pattern.

FIG. 13 is a cross-sectional view of an intermediate process, including forming a first insulating layer and a second insulating layer.

FIG. 14 is a cross-sectional view of an intermediate process, including removing a portion of the first and second insulating layers.

FIG. 15 is a cross-sectional view of an intermediate process, including removing the second etch stop pattern.

FIG. 16 is a cross-sectional view taken along the line A-A′ in FIG. 1B according to some embodiments.

FIGS. 17 through 21 are cross-sectional views, taken along the line A-A′ in FIG. 1B, illustrating methods of forming an integrated circuit device in FIG. 16 according to some embodiments.

FIG. 17 is a cross-sectional view of an intermediate process, including forming a stack structure.

FIG. 18 is a cross-sectional view of an intermediate process, including forming a first mask pattern, a second etch stop pattern, a third etch stop pattern, and a metal via.

FIG. 19 is a cross-sectional view of an intermediate process, including removing the first mask pattern.

FIG. 20 is a cross-sectional view of an intermediate process, including forming a second mask layer.

FIG. 21 is a cross-sectional view of an intermediate process, including removing a portion of the second mask layer.

### DETAILED DESCRIPTION

Metal(s) (e.g., ruthenium (Ru), molybdenum (Mo), tungsten (W), aluminum (Al), and/or copper (Cu)) may be used to form conductive elements (e.g., a metal pattern and a metal via) in a BEOL structure. To simplify the manufacturing process of the BEOL structure, increase the integration degree of various elements in the integrated circuit device, and improve (e.g., reduce) the resistance of the BEOL, a top via scheme utilizing an etchable metal may be used. For example, Ru top via scheme may utilize an etching process of Ru to form a conductive element, such as a metal via and a (lower) metal pattern, and may not require a damascene process.

The top via scheme may face challenges, such as a high (higher) aspect ratio, height deviation of the conductive elements, and hardship in the metal via revealing (at least partially) because the metal pattern and the metal via thereon are formed (almost) simultaneously by the same processes or the same series of processes. For example, a monolithic metal structure comprising the metal pattern and the metal via on the metal pattern may be patterned. Then, some upper portions of the monolithic metal structure may be selectively removed to differentiate the metal patterns without the metal vias thereon from the metal patterns with the metal vias thereon. In other words, the metal pattern and the metal via thereon may be formed at (substantially) the same time by the same processes or the same series of processes. Therefore, the aspect ratio of the monolithic metal structure patterning may be high (higher) because the monolithic metal structure patterning needs to etch the metal at least the height of the metal via plus the height of the metal pattern. In addition, the heights of the metal patterns and the metal vias may vary, while some upper portions of the monolithic metal structure are selectively removed because the metal patterns and the metal vias are parts of the monolithic metal structures, and there is no etch stop pattern between the metal patterns and the metal vias. Also, the heights of the metal vias may further vary or decrease during the metal via revealing process that includes a chemical mechanical polishing (planarization) (CMP) process (CMP buffing) or a non-selective etching because the metal vias are less densely arranged than the metal patterns, and there is no CMP stop pattern (or etch stop pattern) on the metal vias.

According to aspects of the current disclosures, the (lower) metal patterns and the metal vias may be formed by different processes or different sets of processes by utilizing the metal via embedded (hard) mask scheme. Accordingly, the high (higher) aspect ratio, the height variation, and the revealing process issue of the conductive elements in the BEOL described above may be improved.

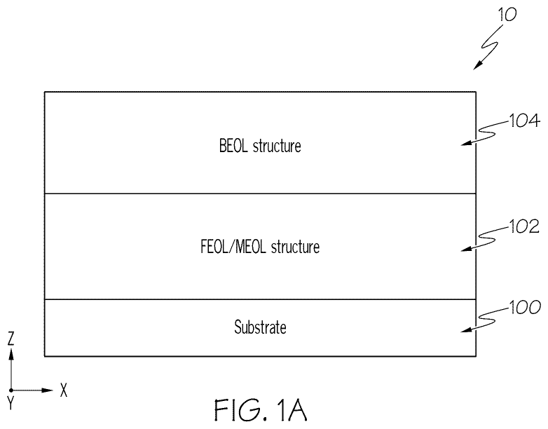

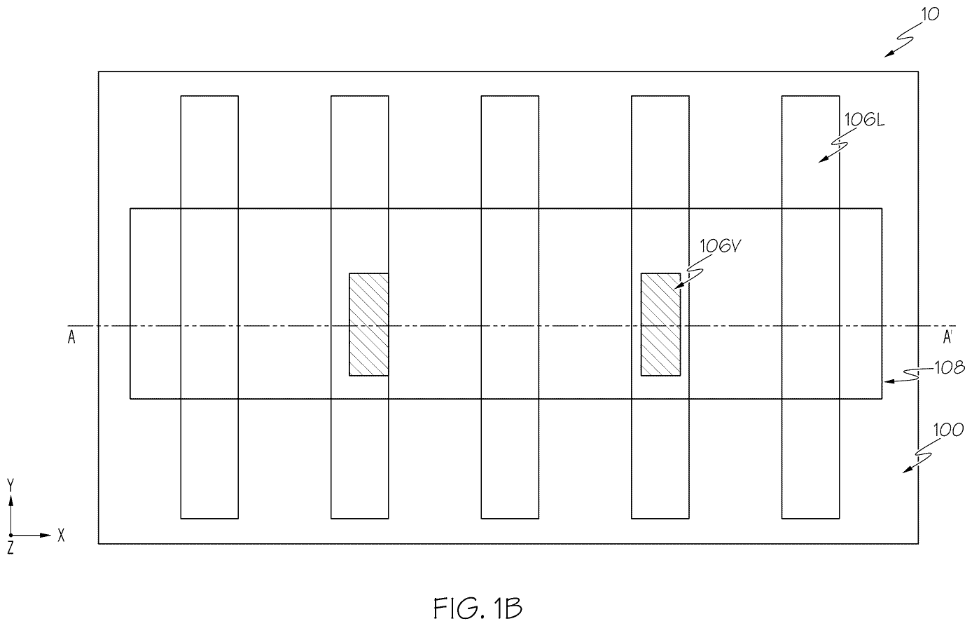

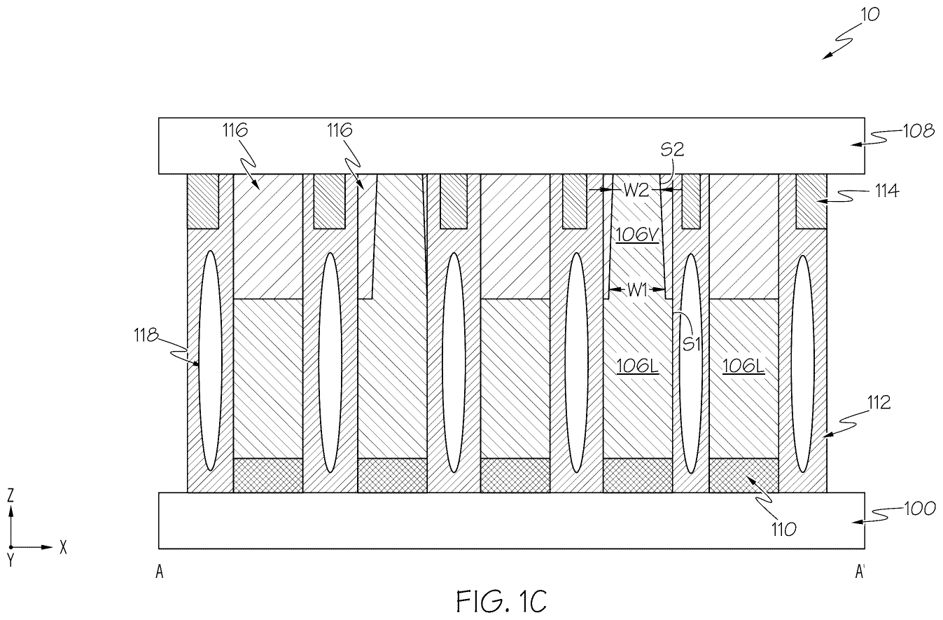

FIG. 1A is a diagram illustrating an integrated circuit device 10 according to some embodiments. The integrated circuit device 10 may include a substrate 100, a front-end-of-line (FEOL)/middle-end-of-line (MEOL) structure 102 that includes elements formed during FEOL and MEOL processes, and a BEOL structure 104 that includes elements formed during a BEOL process. For example, the FEOL/MEOL structure 102 may include transistors and/or capacitors, and the BEOL structure 104 may include conductive elements, such as metal patterns and/or metal vias.

The BEOL structure 104 may be on the substrate 100. The substrate 100 may include semiconductor material(s), for example, Si, Ge, SiGe, GaP, GaAs, SiC, SiGeC and/or InP and/or may include insulating material(s), for example, silicon oxide, silicon oxynitride, silicon nitride, silicon carbonitride and/or a low-k material. In some embodiments, the substrate 100 may be a bulk substrate (e.g., a silicon wafer), a semiconductor on insulator (SOI) substrate or an insulating layer (e.g., a monolithic insulating layer). Herein, the low-k material may be a material having a dielectric constant lower than that of silicon oxide. The low-k material may include, for example, SiCOH, fluorine-doped silicon oxide, organosilicate glass, carbon-doped oxide, porous silicon dioxide, porous organosilicate glass, spin-on organic polymeric dielectrics and/or spin-on silicon based polymeric dielectric. In some embodiments, the FEOL/MEOL structure 102 may be between the BEOL structure 104 and the substrate 100 in a first direction (e.g., Z-direction) that is perpendicular to an upper surface (and/or a lower surface) of the substrate 100.

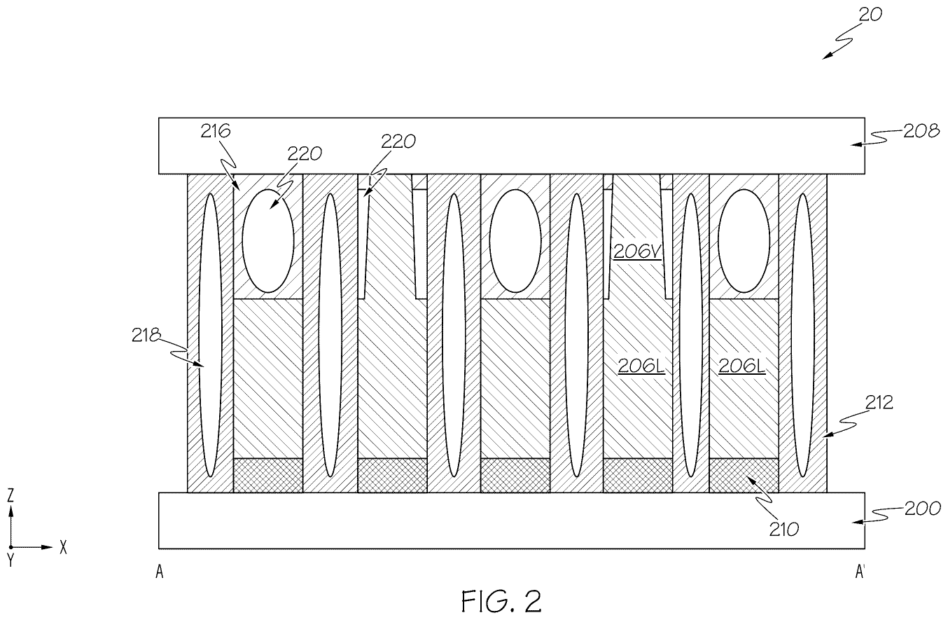

FIG. 1B is a layout of the BEOL structure 104 of the integrated circuit device 10 according to some embodiments. FIG. 1C is a cross-sectional view taken along the line A-A′ in FIG. 1B according to some embodiments. FIG. 2 is a cross-sectional view taken along the line A-A′ in FIG. 1B according to some embodiments.

Referring to FIGS. 1B and 1C, the BEOL structure 104 may include a first metal pattern 106L (also referred to as a lower metal pattern 106L), a metal via 106V, and a second metal pattern 108 (also referred to as an upper metal pattern 108). The first metal pattern 106L may extend longitudinally in a second direction (e.g., Y-direction), and the second metal pattern 108 may extend longitudinally in a third direction (e.g., X-direction). The second direction and the third direction may be parallel with the upper surface (and/or the lower surface) of the substrate 100. The second direction may intersect the third direction. In some embodiments, the second metal pattern 108 may traverse a plurality of the first metal patterns 106L. For example, the second metal pattern 108 may overlap the plurality of the first metal patterns 106L in the first direction. In some embodiments, the second metal pattern 108 may traverse a plurality of the metal vias 106V. For example, the second metal pattern 108 may overlap the plurality of the metal vias 106V in the first direction. As used herein, “an element A overlapping an element B in a direction C” (or similar language) means that there is at least one line that extends in the direction C and intersects both the elements A and B.

The metal via 106V may be between the (corresponding) first metal pattern 106L and the (corresponding) second metal pattern 108 in the first direction. For example, the metal via 106V may overlap the (corresponding) first metal pattern 106L and the (corresponding) second metal pattern 108 in the first direction. In some embodiments, the metal via 106V may be electrically connected to (e.g., in contact with) the first metal pattern 106L. In some embodiments, the first metal pattern 106L and the metal via 106V may include the same material. For example, the first metal pattern 106L and the metal via 106V may include, for example, metal, such as Ru and/or Mo, but the embodiments are not limited thereto. In some embodiments, the metal via 106V and the (corresponding) first metal pattern 106L may be integrated with each other as a monolithic metal structure 106. A monolithic structure (e.g., the monolithic metal structure 106) herein may refer to a structure (e.g., a continuum) without a (visible) boundary between its sub-structures (e.g., the metal via 106V and the first metal pattern 106L). In some embodiments, the metal via 106V may be electrically connected to (e.g., in contact with) the second metal pattern 108. In some embodiments, the second metal pattern 108 may include, for example, a metal, such as Ru, Mo, W, Cu, and/or Al, but the embodiments are not limited thereto.

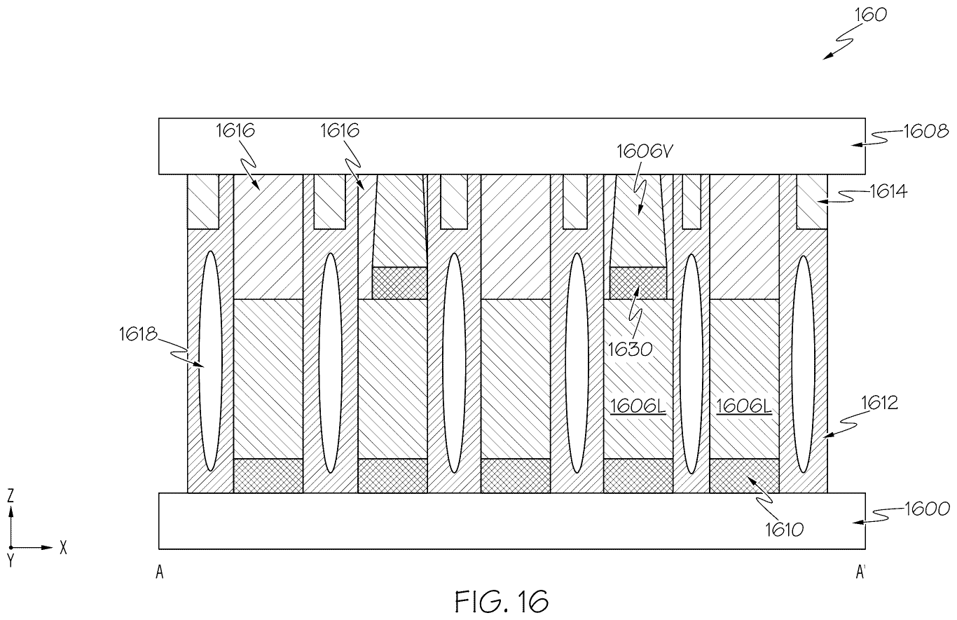

In some embodiments, the BEOL structure 104 may further include a first etch stop pattern 110 between the first metal pattern 106L and the substrate 100 in the first direction. In some embodiments, the BEOL structure 104 may further include a third etch stop pattern (refer to, for example, a third etch stop pattern 1630 illustrated in FIG. 16) between the first metal pattern 106L and the (corresponding) metal via 106V in the first direction. The first etch stop pattern 110 may have an etch selectivity with respect to the monolithic metal structure 106 (the first metal pattern 106L and the metal via 106V). For example, the first etch stop pattern 110 may include a material, such as TaN, having an etch selectivity with respect to metal, such as Ru, in the monolithic metal structure 106.

In some embodiments, at least one of the plurality of the first metal patterns 106L may not have the (corresponding) metal via 106V thereon. For example, at least one of the plurality of the first metal patterns 106L may be free of contact with the metal via 106V. In some embodiments, at least one of the plurality of the first metal patterns 106L may not overlap the metal via 106V in the first direction.

In some embodiments, a side surface of the metal via 106V may be non-coplanar (misaligned) with a (the corresponding) side surface of the (corresponding) first metal pattern 106L. For example, a side surface of the metal via 106V may not be aligned with a (the corresponding) side surface of the (corresponding) first metal pattern 106L in the third direction. In some embodiments, the side surface of the metal via 106V and the (corresponding) side surface of the (corresponding) first metal pattern 106L may extend in the first direction. For example, the side surface of the metal via 106V and the (corresponding) side surface of the (corresponding) first metal pattern 106L may not aligned with each other in the first direction.

In some embodiments, a side surface of the first metal pattern 106L may have a first slope S1 with respect to the first direction, and a (the corresponding) side surface of the (corresponding) metal via 106V may have a second slope S2 with respect to the first direction. The second slope S2 may be different from the first slope S1. The first slope S1 may be zero slope, which means that the side surface of the first metal pattern 106L may extends (substantially) in the first direction.

In some embodiments, a first width W1 in the third direction of a lower surface of the metal via 106V may be greater than a second width W2 in the third direction of an upper surface of the metal via 106V, but the embodiments are not limited thereto. A width in the third direction of the metal via 106V may decrease in a direction away from the (corresponding) first metal pattern 106L (in the first direction).

In some embodiments, the monolithic metal structure 106 may have a step profile between the metal via 106V and the first metal pattern 106L in the first direction. For example, the step profile may be at (coplanar with) a lower surface of the metal via 106V and/or at an upper surface of the first metal pattern 106L.

In some embodiments, a width in the second direction of the upper surface of the first metal pattern 106L may be greater than a width in the second direction of the lower surface of the (corresponding) metal via 106V. In some embodiments, a width in the third direction of the upper surface of the first metal pattern 106L may be greater than a width in the third direction of the lower surface of the (corresponding) metal via 106V.

In some embodiments, the BEOL structure 104 may further include a first insulating pattern 112, a second insulating pattern 114, and a third insulating pattern 116. Each of the first insulating pattern 112, the second insulating pattern 114, and the third insulating pattern 116 may include, for example, an insulating material (e.g., SiO, SiN, SiON or low-k material). The first insulating pattern 112 may extend around the first metal pattern 106L and the metal via 106V. The first insulating pattern 112 may extend around the first etch stop pattern 110. The first insulating pattern 112 may extend around the third etch stop pattern. For example, the first insulating pattern 112 may overlap the first metal pattern 106L and the metal via 106V in the third direction (and/or the second direction). The first insulating pattern 112 may overlap the first etch stop pattern 110 in the third direction (and/or the second direction). The first insulating pattern 112 may overlap the third etch stop pattern in the third direction (and/or the second direction). In some embodiments, the first insulating pattern 112 may be between adjacent ones of the plurality of the first metal patterns 106L (in the third direction). For example, the first insulating pattern 112 may be on (may be in contact with) the upper surface of the substrate 100.

The second insulating pattern 114 may be on (in) the first insulating pattern 112. For example, the first insulating pattern 112 may extend around the second insulating pattern 114. For example, the first insulating pattern 112 may overlap the second insulating pattern 114 in the third direction. The second insulating pattern 114 may extend around the metal via 106V. For example, the second insulating pattern 114 may overlap the metal via 106V in the third direction. In some embodiments, the first insulating pattern 112 and the second insulating pattern 114 may include a same material. For example, the first insulating pattern 112 and the second insulating pattern 114 may be integrated with each other as a monolithic insulating structure.

The third insulating pattern 116 may be on the first metal pattern 106L. In some embodiments, the third insulating pattern 116 may be on (may be in contact with) the upper surface of the first metal pattern 106L. For example, the third insulating pattern 116 may overlap the first metal pattern 106L in the first direction. The third insulating pattern 116 may extend around the metal via 106V. In some embodiments, the third insulating pattern 116 may overlap the metal via 106V in the third direction. For example, the third insulating pattern 116 may be on (may be in contact with) a side surface of the metal via 106V. In some embodiments, an upper surface of the metal via 106V may be coplanar with an upper surface of the third insulating pattern 116 in the first direction.

The first insulating pattern 112 may extend around the third insulating pattern 116. In some embodiments, the first insulating pattern 112 may overlap the third insulating pattern 116 in the third direction. For example, the first insulating pattern 112 may be on (may be in contact with) a side surface of the third insulating pattern 116. The first insulating pattern 112 may be between adjacent ones of a plurality of the third insulating patterns 116 (in the third direction). In some embodiments, the plurality of the first insulating patterns 112 and the plurality of the third insulating pattern 116 may be alternately arranged in the third direction. The third insulating pattern 116 may be different from the first insulating pattern 112. For example, the third insulating pattern 116 may have a different material feature from that of the first insulating pattern 112. In some embodiments, the upper surface of the third insulating pattern 116 may be coplanar with an upper surface of the first insulating pattern 112 and an upper surface of the metal via 106V in the first direction.

The second insulating pattern 114 may extend around the third insulating pattern 116. In some embodiments, the second insulating pattern 114 may overlap the third insulating pattern 116 in the third direction. The second insulating pattern 114 may be between adjacent ones of the plurality of the third insulating patterns 116 (in the third direction). In some embodiments, the plurality of the second insulating patterns 114 and the plurality of the third insulating pattern 116 may be alternately arranged in the third direction. The third insulating pattern 116 may be different from the second insulating pattern 114. For example, the third insulating pattern 116 may have a different material feature from that of the second insulating pattern 114. In some embodiments, an upper surface of the second insulating pattern 114 may be coplanar with the upper surface of the third insulating pattern 116 in the first direction.

In some embodiments, a width in the third direction of an upper surface of the third insulating pattern 116 may be greater than a width in the third direction of a lower surface of the third insulating pattern 116, but the embodiments are not limited thereto. A width in the third direction of the third insulating pattern 116 may increase in a direction away from the (corresponding) first metal pattern 106L (in the first direction).

The first insulating pattern 112 may include a first air gap 118. Herein, the “air gap” may refer to a vacant space (also referred to as a void) or a space (e.g., a pocket) that is (at least partially) filled with air or gas. In some embodiments, the first air gap 118 may overlap the first metal pattern 106L and the metal via 106V (in the third direction). In some embodiments, the first air gap 118 may overlap the third insulating pattern 116 (in the third direction). For example, the first air gap 118 may be between adjacent ones of the plurality of the third insulating patterns 116 (in the third direction). The first air gap 118 may be between adjacent ones of the plurality of the first metal patterns 106L (in the third direction).

Referring to FIG. 2, the integrated circuit device 20 may correspond to the integrated circuit device 10 in FIGS. 1B and 1C. The substrate 100, the first etch stop pattern 110, the first insulating pattern 112, the third insulating pattern 116, the first metal pattern 106L, the metal via 106V, the second metal pattern 108, and the first air gap 118 in FIG. 1C may correspond to the substrate 200, the first etch stop pattern 210, the first insulating pattern 212, the third insulating pattern 216, the first metal pattern 206L, the metal via 206V, the second metal pattern 208, and the first air gap 218 in FIG. 2, respectively. The integrated circuit device 20 in FIG. 2 may be configured the same as or (substantially) similar to the example embodiments described with reference to FIG. 1C, other than the configuration in which at least one of the plurality of the third insulating patterns 216 may include a second air gap 220. In some embodiments, the second air gap 220 may expose a portion of the metal via 206V and/or a portion of the first metal pattern 206L. For example, the second air gap 220 may expose a side surface of the metal via 206V and/or an upper surface of the first metal pattern 206L. In some embodiments, the second air gap 220 may overlap the (corresponding) first metal pattern 206L in the first direction. In some embodiments, the first air gap 218 may overlap the second air gap 220 in the third direction. In some embodiments, the first insulating pattern 212 may overlap the second air gap 220 in the third direction.

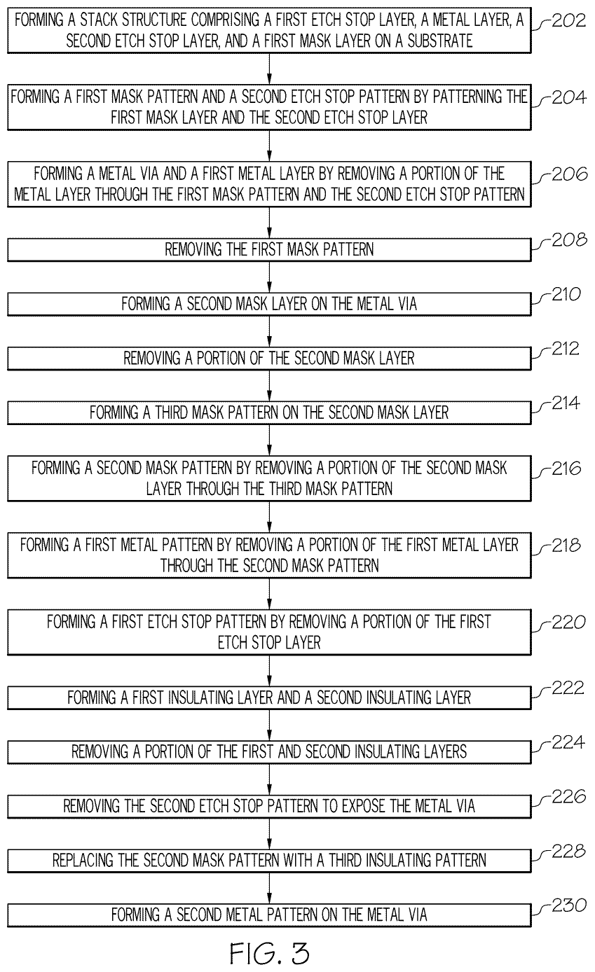

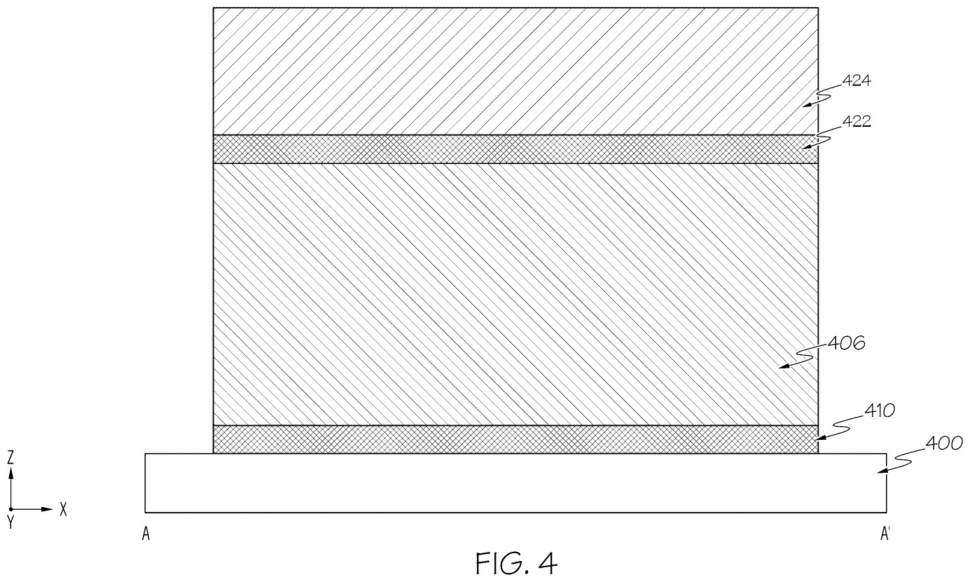

FIG. 3 is a flow chart of methods of forming an integrated circuit device according to some embodiments. The steps 202-230 of FIG. 3 will be explained in conjunction with FIGS. 4 through 20. FIGS. 4 through 15 are cross-sectional views, taken along the line A-A′ in FIG. 1B, illustrating methods of forming the integrated circuit device 10 in FIG. 1C or the integrated circuit device 20 in FIG. 2 according to some embodiments.

FIG. 4 is a cross-sectional view of an intermediate process, including forming a stack structure. Referring to FIGS. 3 and 4, the methods may include forming a stack structure comprising a first etch stop layer 410, a metal layer 406, a second etch stop layer 422, and a first mask layer 424 sequentially stacked on a substrate 400 in the first direction (Block 202). In some embodiments, the substrate 400 may include semiconductor material(s), for example, Si, Ge, SiGe, GaP, GaAs, SiC, SiGeC and/or InP and/or may include insulating material(s), for example, silicon oxide, silicon oxynitride, silicon nitride, silicon carbonitride and/or a low-k material. In some embodiments, the substrate 400 may be a bulk substrate (e.g., a silicon wafer), a semiconductor on insulator (SOI) substrate or an insulating layer (e.g., a monolithic insulating layer). In some embodiments, the metal layer 406 may include for example, metal, such as Ru and/or Mo. In some embodiments, each of the first and second etch stop layers 410 and 422 may include a material, such as TaN, having an etch selectivity with respect to (metal, such as Ru, in) the metal layer 406. In some embodiments, the first mask layer 424 may be a hard mask layer. For example, the first mask layer 424 may include TiN and/or tungsten doped carbon (WDC), but the embodiments are not limited thereto.

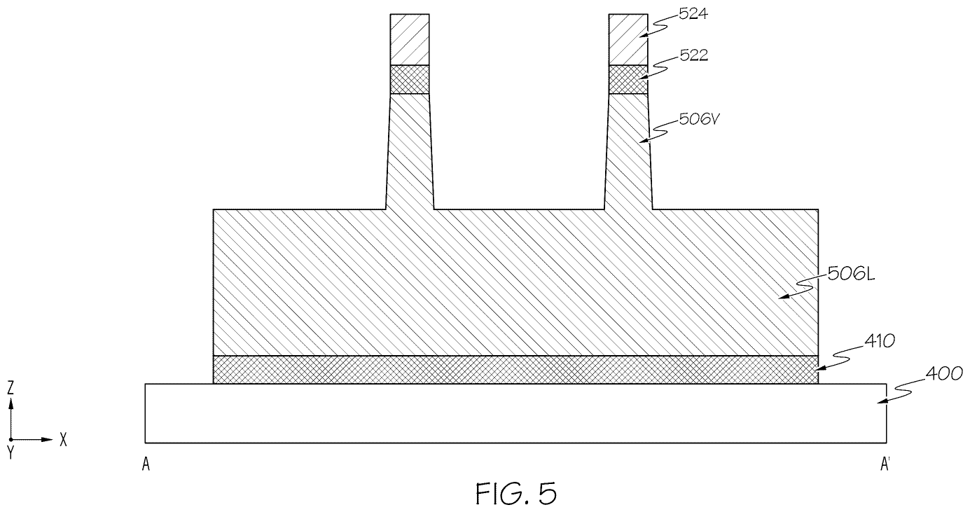

FIG. 5 is a cross-sectional view of an intermediate process, including forming a first mask pattern 524, a second etch stop pattern 522, and a metal via 506V. Referring to FIGS. 3 and 5, the methods may include forming the first mask pattern 524 by patterning the first mask layer 424 (Block 204). The second etch stop pattern 522 may be formed by patterning the second etch stop layer 422 through the first mask pattern 524 (Block 204). The metal via 506V may be formed by removing a portion (e.g., an upper portion) of the metal layer 406 through the first mask pattern 524 and the second etch stop pattern 522 (Block 206). A lower portion of the metal layer 406 may remain as a first metal layer 506L (also referred to as a lower metal layer 506L).

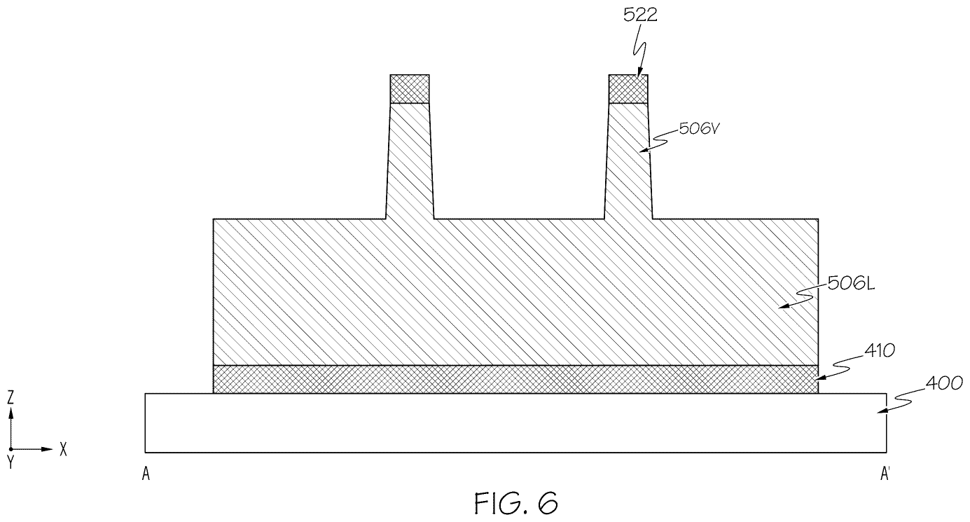

FIG. 6 is a cross-sectional view of an intermediate process, including removing the first mask pattern 524. Referring to FIGS. 3 and 6, the first mask pattern 524 may be removed (Block 208).

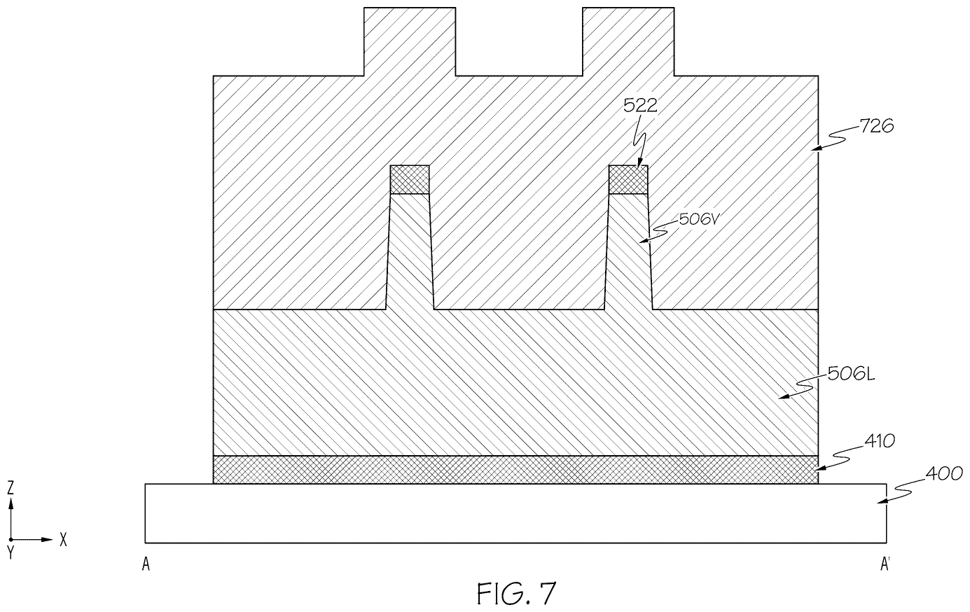

FIG. 7 is a cross-sectional view of an intermediate process, including forming a second mask layer 726. Referring to FIGS. 3 and 7, the second mask layer 726 may be formed on the metal via 506V and/or the first metal layer 506L (Block 210). The second mask layer 726 may extend around the metal via 506V. In some embodiments, a portion of the second mask layer 726 may protrude (in the first direction) according to the profile of the metal via 506V. In some embodiments, the second mask layer 726 may be a hard mask layer. For example, the second mask layer 726 may include TiN and/or tungsten doped carbon (WDC), but the embodiments are not limited thereto.

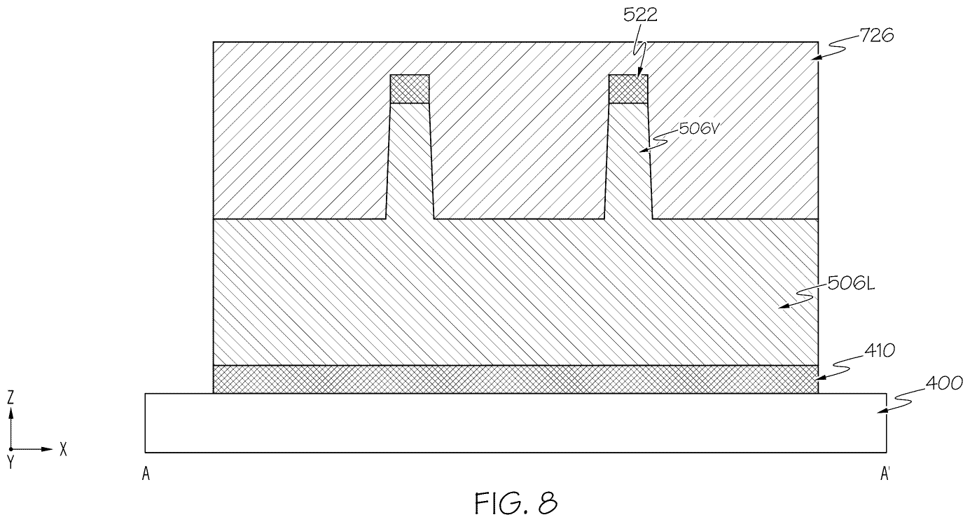

FIG. 8 is a cross-sectional view of an intermediate process, including removing a portion of the second mask layer 726. Referring to FIGS. 3 and 8, a portion of the second mask layer 726 may be removed (Block 212). In some embodiments, the portion of the second mask layer 726 may be removed by a CMP process. An upper surface of the second mask layer 726 may be (substantially) planarized (e.g., may become (substantially) flat). In some embodiments, an upper portion of the second mask layer 726 may be removed. For example, the protruding portion of the second mask layer 726 may be removed.

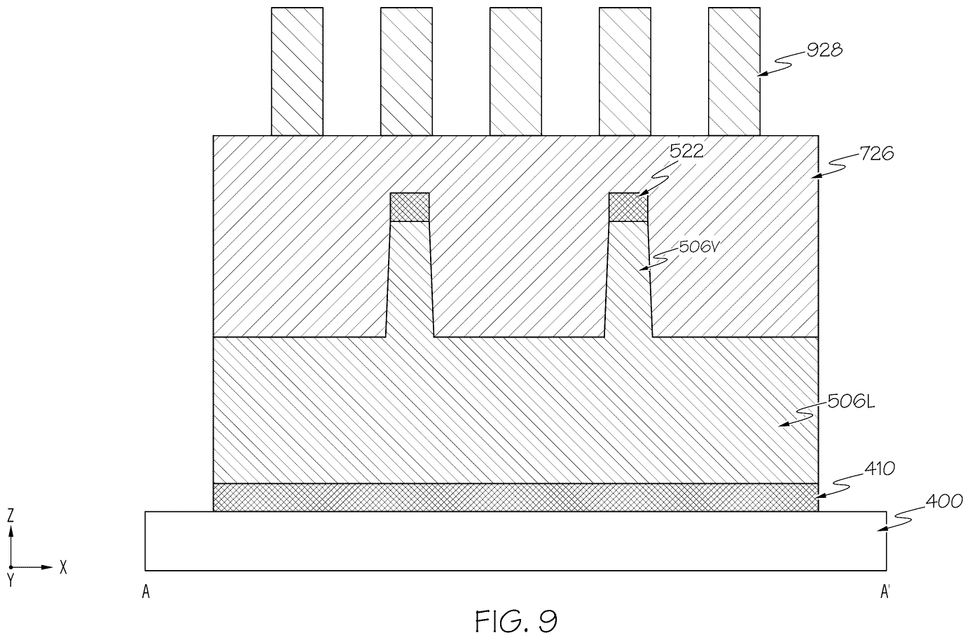

FIG. 9 is a cross-sectional view of an intermediate process, including forming a third mask pattern 928. Referring to FIGS. 3 and 9, the third mask pattern 928 (also referred to as a pillar 928) may be formed on the second mask layer 726 (Block 214). The third mask pattern 928 may overlap the metal via 506V in the first direction. The third mask pattern 928 may be formed by, for example, a direct patterning of a mask layer with high numerical aperture (NA) lithography equipment for mandrel scheme with spacer application. The third mask pattern 928 may include, for example, SiN and/or SiO, but the embodiments are not limited thereto. In some embodiments, a width in the third direction of the third mask pattern 928 may be equal to or greater than a width in the third direction of (an upper surface of) the metal via 506V.

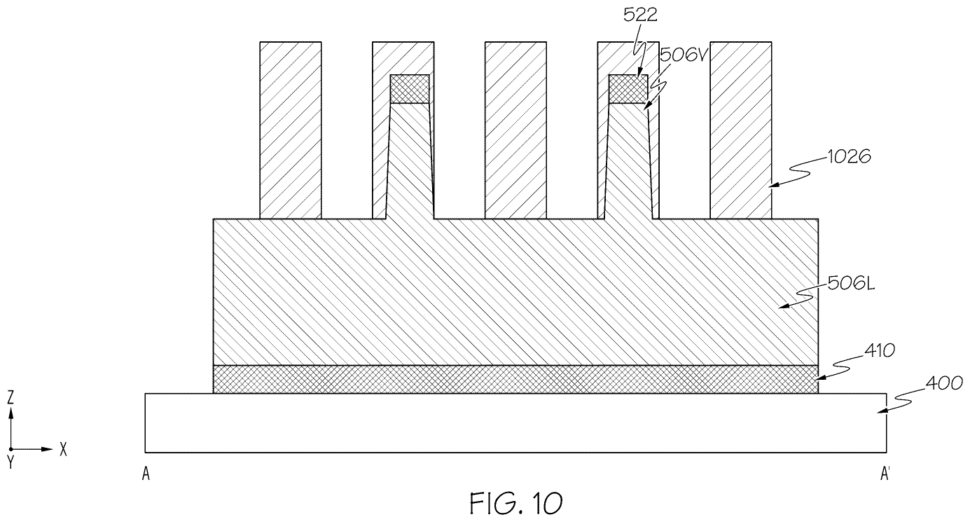

FIG. 10 is a cross-sectional view of an intermediate process, including forming a second mask pattern 1026. Referring to FIGS. 3 and 10, a portion of the second mask layer 726 may be removed (e.g., patterned) through the third mask pattern 928 to form a second mask pattern 1026 (Block 216). The second mask pattern 1026 may overlap the metal via 506V (and/or the second etch stop pattern 522) in the first direction. For example, the metal via 506V and the second etch stop pattern 522 may be (embedded) in the second mask pattern 1026. Herein, the second mask patterns 1026 may be referred to as metal via embedded hard masks because at least one of the second mask patterns 1026 may include the metal via 506V therein. In other words, each individual second mask patterns 1026 may be referred to as a metal via embedded hard mask with or without the metal via 506V therein as long as at least one of the second mask patterns 1026 has the metal via 506V therein. In some embodiments, a width in the third direction of the second mask pattern 1026 may be equal to or greater than a width in the third direction of (the upper surface of) the metal via 506V (and/or a width in the third direction of (the upper surface of) the second etch stop pattern 522). The third mask pattern 928 may be removed after (or during) the formation of the second mask pattern 1026.

In some embodiments, a central portion (e.g., the center) of at least one of the metal vias 506V in the third direction may be aligned with a central portion (e.g., the center) of (corresponding) one of the second mask patterns 1026 in the third direction. In some embodiments, a central portion (e.g., the center) of at least one of the metal vias 506V in the third direction may not be aligned with a central portion (e.g., the center) of (corresponding) one of the second mask patterns 1026 in the third direction. In some embodiments, a side surface of at least one of the metal vias 506V may be aligned with a (corresponding) side surface of (corresponding) one of the second mask patterns 1026 in the third direction. In some embodiments, a side surface of at least one of the metal vias 506V may not be aligned with a (corresponding) side surface of (corresponding) one of the second mask patterns 1026 in the third direction.

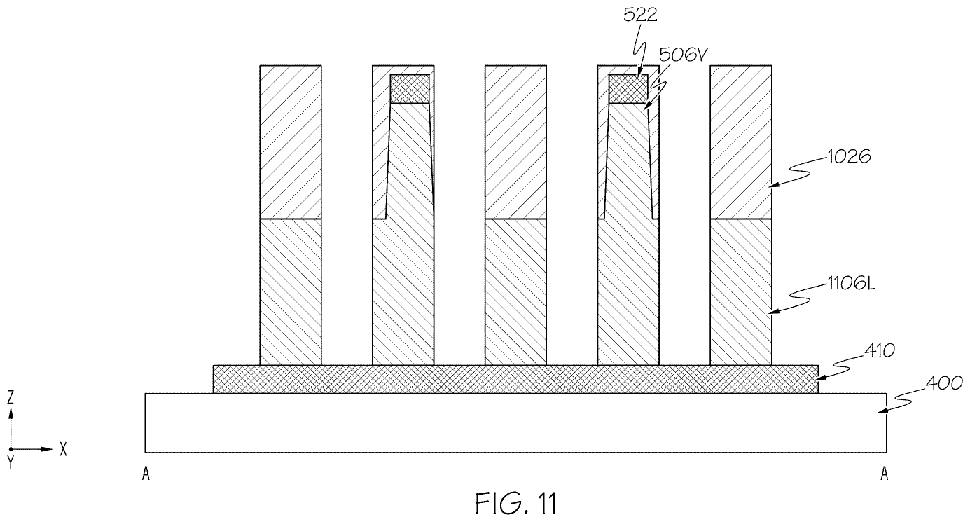

FIG. 11 is a cross-sectional view of an intermediate process, including forming a first metal pattern 1106L. Referring to FIGS. 3 and 11, the first metal pattern 1106L may be formed by removing a portion of the first metal layer 506L through the second mask pattern 1026 (the metal via embedded hard mask) (Block 218). The second etch stop pattern 522 may prevent the loss of the metal via 506V during the patterning of the first metal pattern 1106L.

In some embodiments, a central portion (e.g., the center) in the third direction of the third mask pattern 928 may not be aligned with a central portion (e.g., the center) in the third direction of the metal via 506V in the third direction. As long as the second etch stop pattern 522 is included (embedded) in the second mask pattern 1026, the first metal pattern 1106L can be formed. In this case, a portion (a lower portion of one side surface) of the metal via 506V may be removed during the formation of the first metal pattern 1106L. As a result, the metal via 506 may have an asymmetric shape in the third direction. For example, one side surface of the metal via 506 may extend with a slope with respect to the first direction, and the opposite side surface of the metal via 506 may extend (substantially) along the first direction. The width in the third direction of the metal via 506 may decrease in a direction away from the first metal pattern 1106L in the first direction.

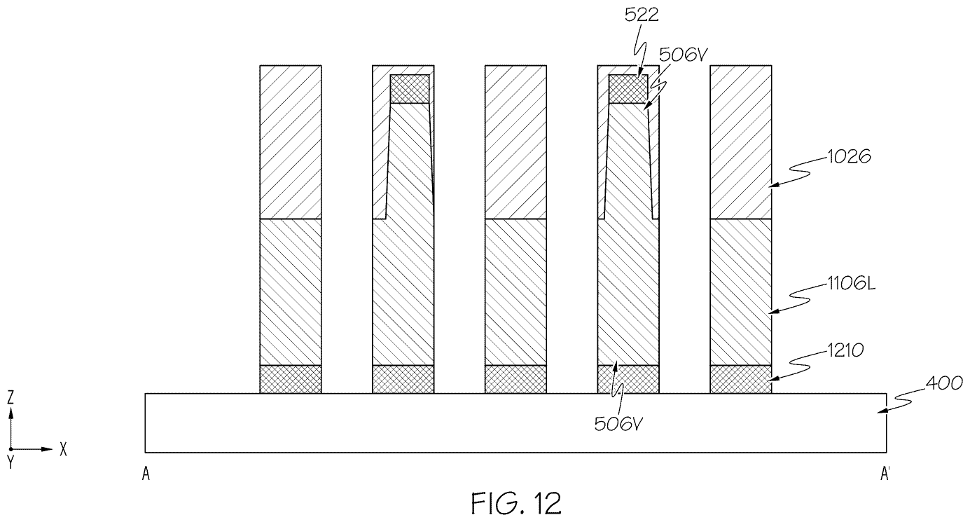

FIG. 12 is a cross-sectional view of an intermediate process, including forming a first etch stop pattern 1210. Referring to FIGS. 3 and 12, the first etch stop pattern 1210 may be formed by removing a portion of the first etch stop layer 410 through the second mask pattern 1026 (the metal via embedded hard mask) (Block 220). A portion of the upper surface of the substrate 400 may be exposed by removing the portion of the first etch stop layer 410.

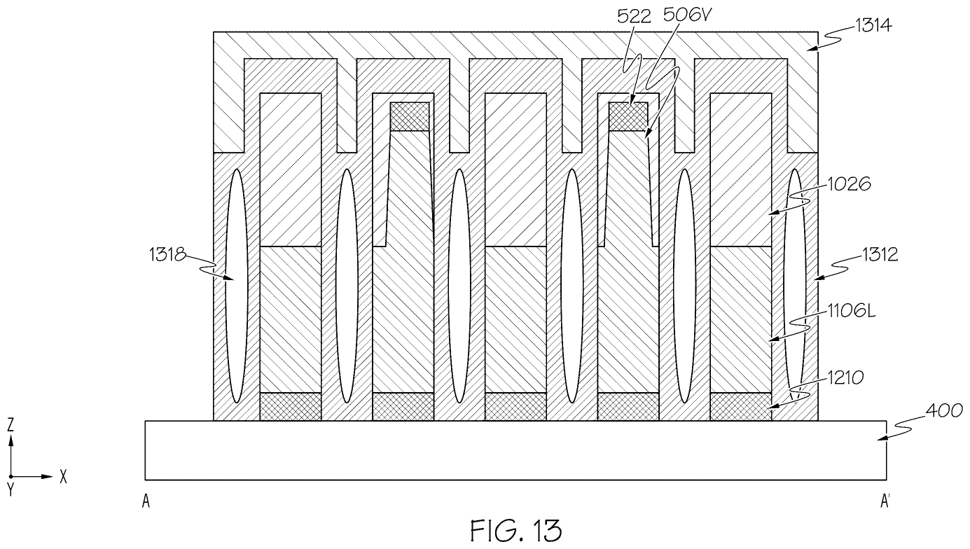

FIG. 13 is a cross-sectional view of an intermediate process, including forming a first insulating layer 1312 and a second insulating layer 1314. Referring to FIGS. 3 and 13, the first insulating layer 1312 may be formed between adjacent ones of the second mask patterns 1026 in the third direction (Block 222). The second insulating layer 1314 may be formed on the first insulating layer 1312 (Block 222). Each of the first insulating layer 1312 and the second insulating layer 1314 may include an insulating material (e.g., SiO, SiN, SiON or low-k material). The first insulating layer 1312 may extend around the first metal pattern 1106L and the metal via 506V. For example, the first insulating layer 1312 may overlap the first metal pattern 1106L and the metal via 506V in the third direction. The second insulating layer 1314 may extend around the metal via 506V. For example, the second insulating layer 1314 may overlap the metal via 506V in the third direction. In some embodiments, the first insulating layer 1312 and the second insulating layer 1314 may include a same material. For example, the first insulating layer 1312 and the second insulating layer 1314 may be integrated as a monolithic insulating structure.

In some embodiments, a first air gap 1318 may be formed in the first insulating layer 1312. The first air gap 1318 may overlap the first metal pattern 1106L and the metal via 506V (in the third direction).

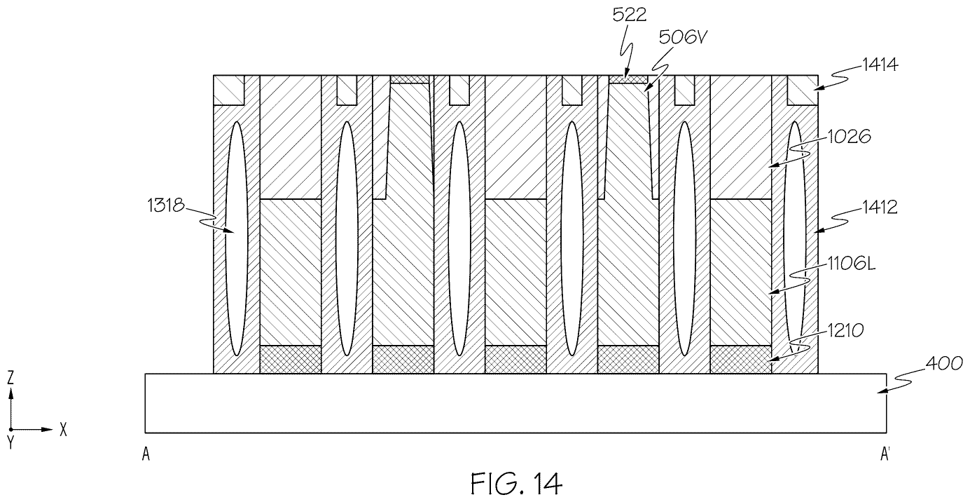

FIG. 14 is a cross-sectional view of an intermediate process, including removing a portion of the first and second insulating layers 1312 and 1314. Referring to FIGS. 3 and 14, the first insulating pattern 1412 and the second insulating pattern 1414 may be formed by removing a portion of the first and second insulating layers 1312 and 1314 (Block 224). In some embodiments, the portion of the first and second insulating layers 1312 and 1314 may be removed by a CMP process (e.g., a CMP buffing) and/or a non-selective etching. The CMP process and/or the non-selective etching may be stopped by the second mask pattern 1026 (the metal via embedded hard mask). In some embodiments, an upper surface of the second etch stop pattern 522 and an upper surface of the second mask pattern 1026 may be exposed by the CMP process or the non-selective etching.

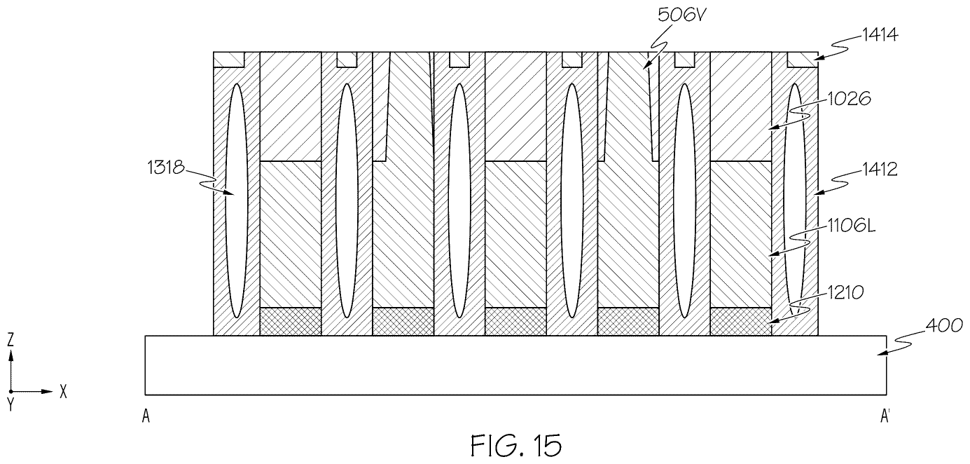

FIG. 15 is a cross-sectional view of an intermediate process, including removing the second etch stop pattern 522. Referring to FIGS. 3 and 15, the second etch stop pattern 522 may be removed by a CMP process (e.g., a CMP buffing) or a non-selective etching to expose (an upper surface of) the metal via 506V (Block 226).

Referring to FIGS. 1C and 3, the second mask pattern 1026 may be replaced with a third insulating pattern 116 (Block 228). In some embodiments, the third insulating pattern 116 may include a material having at least one different feature from those of the first insulating layer 1312 (or the first insulating pattern 1412) and the second insulating layer 1314 (or the second insulating pattern 1414). For example, the second mask pattern 1026 may be removed by a selective wet clean process without removing (without loss of) the metal structure (e.g., the metal via 506V or the first metal pattern 1106L) and the third insulating pattern 116 may be formed in the space from which the second mask pattern 1026 was removed. As the second mask pattern 1026 is replaced with the third insulating pattern 116 that includes a dielectric material, such as a low-K material, a low-K stop CMP or deposition-etch back scheme may be used in the later processes. The second metal pattern 108 may be formed on the third insulating pattern 116 and the metal via 506V (Block 230).

Referring to FIGS. 2 and 3, the third insulating pattern 216 (corresponding to the third insulating pattern 116 in FIG. 1C) may include the second air gap 220.

FIG. 16 is a cross-sectional view taken along the line A-A′ in FIG. 1B according to some embodiments. The substrate 100, the first etch stop pattern 110, the first insulating pattern 112, the second insulating pattern 114, the third insulating pattern 116, the first metal pattern 106L, the metal via 106V, the second metal pattern 108, and the first air gap 118 in FIG. 1C may correspond to the substrate 1600, the first etch stop pattern 1610, the first insulating pattern 1612, the second insulating pattern 1614, the third insulating pattern 1616, the first metal pattern 1606L, the metal via 1606V, the second metal pattern 1608, and the first air gap 1618 in FIG. 16, respectively. The integrated circuit device 160 in FIG. 16 may be configured the same as or (substantially) similar to the integrated circuit device 10 described with reference to FIG. 1C, other than the configuration in which a third etch stop pattern 1630 is between the first metal pattern 1606L and the metal via 1606V in the first direction.

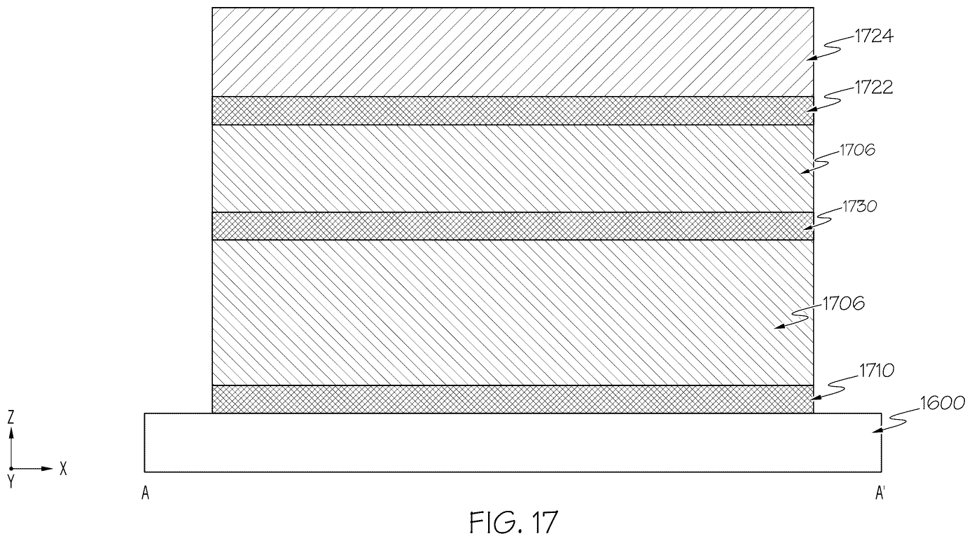

FIGS. 17 through 21 are cross-sectional views, taken along the line A-A′ in FIG. 1B, illustrating methods of forming an integrated circuit device 160 in FIG. 16 according to some embodiments. The methods of FIGS. 17 through 21 may be the same as or (substantially) similar to the methods described with reference to FIG. 3 and FIGS. 4-8, other than the inclusion of a third etch stop pattern between the first metal pattern and the metal via in the first direction.

FIG. 17 is a cross-sectional view of an intermediate process, including forming a stack structure. The intermediate process described in FIG. 17 may be the same as or (substantially) similar to the intermediate process described in FIG. 4 (and Block 202 of FIG. 3), other than a third etch stop layer 1730. Referring to 17, the methods of forming the integrated circuit device 160 may include forming a stack structure comprising a first etch stop layer 1710, a metal layer 1706, a second etch stop layer 1722, and a first mask layer 1724 sequentially stacked on a substrate 1600 in the first direction. The methods may include forming the third etch stop layer 1730 in the metal layer 1706. The third etch stop layer 1730 may be between the first etch stop layer 1710 and the second etch stop layer 1722 in the first direction. In some embodiments, the third etch stop layer 1730 may include a material, such as TaN, having an etch selectivity with respect to (metal in) the metal layer 1706. In some embodiments, each of the first, second, and third etch stop layers 1730 may include a same material.

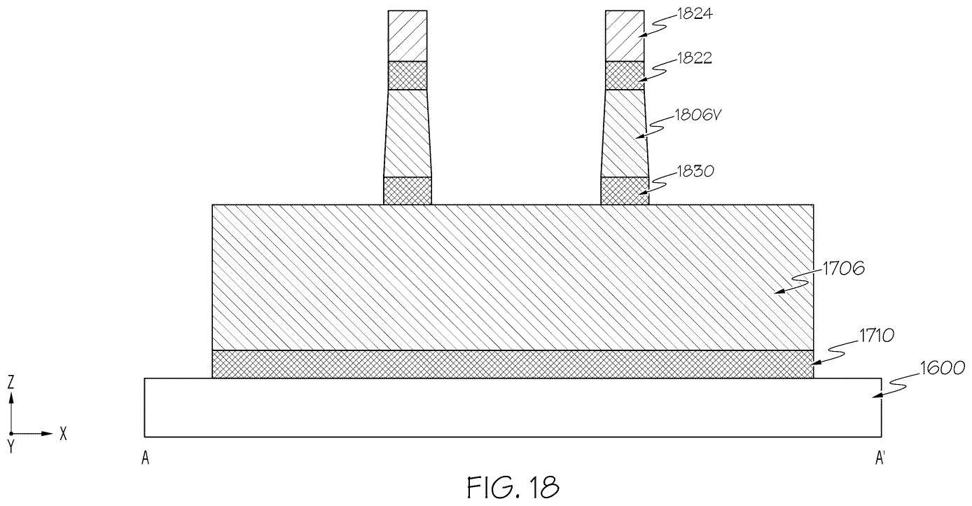

FIG. 18 is a cross-sectional view of an intermediate process, including forming a first mask pattern 1824, a second etch stop pattern 1822, a metal via 1806V, and a third etch stop pattern 1830. The intermediate process described in FIG. 18 may be the same as or (substantially) similar to the intermediate process described in FIG. 5 (and Block 204 and Block 206 of FIG. 3), other than the third etch stop pattern 1830.

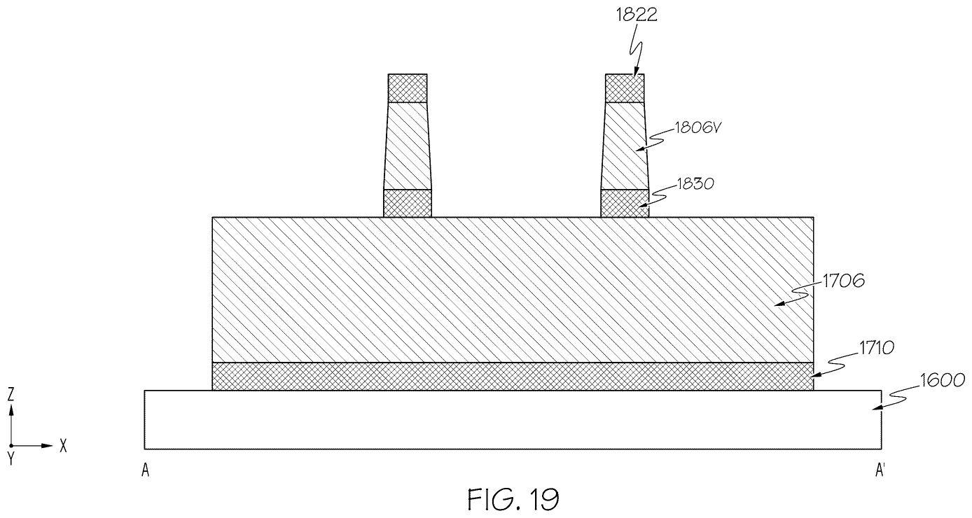

FIG. 19 is a cross-sectional view of an intermediate process, including removing the first mask pattern 1824. The intermediate process described in FIG. 19 may be the same as or (substantially) similar to the intermediate process described in FIG. 6 (and Block 208 of FIG. 3), other than the third etch stop pattern 1830.

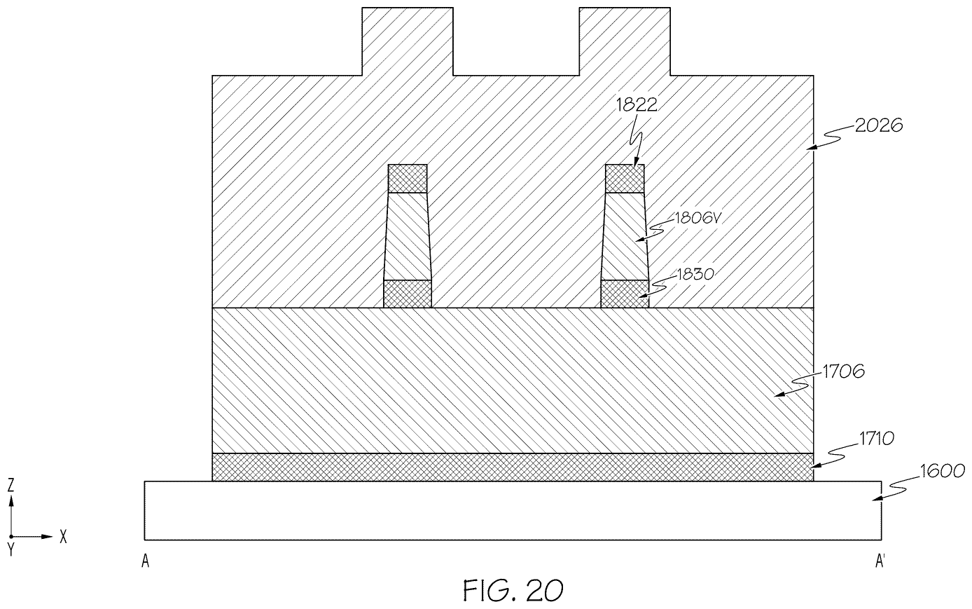

FIG. 20 is a cross-sectional view of an intermediate process, including forming a second mask layer 2026. The second mask layer 2026 may be formed on the metal via 1806V and/or the metal layer 1706. The intermediate process described in FIG. 20 may be the same as or (substantially) similar to the intermediate process described in FIG. 7 (and Block 210 of FIG. 3), other than the third etch stop pattern 1830.

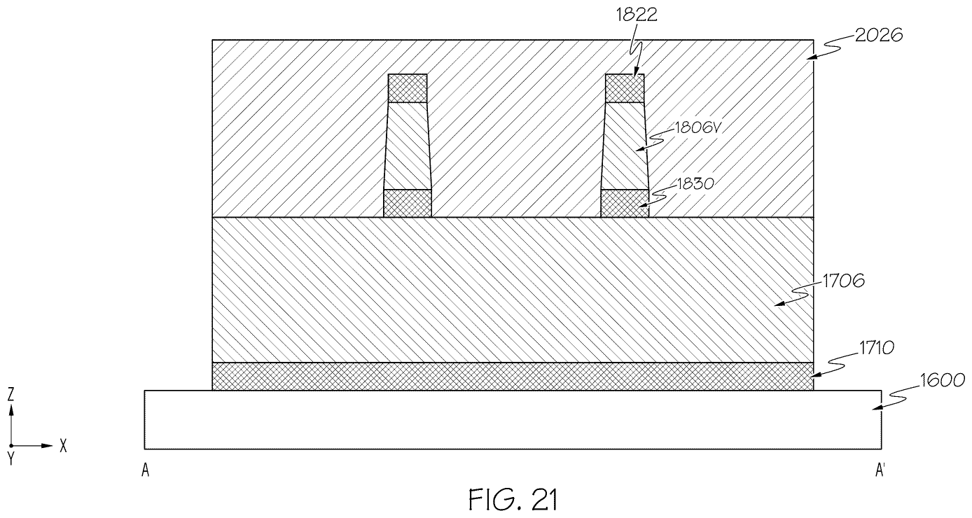

FIG. 21 is a cross-sectional view of an intermediate process, including removing a portion of the second mask layer 2026. The intermediate process described in FIG. 21 may be the same as or (substantially) similar to the intermediate process described in FIG. 8 (and Block 212 of FIG. 3), other than the third etch stop pattern 1830. The following intermediate processes may be the same as or (substantially) similar to the intermediate processes described in FIGS. 9-15 (and Blocks 214, 216, 218, 220, 222, 224, 226, 228, and 230 of FIG. 3), referring to the configuration described in FIG. 16.

Example embodiments described herein show that the monolithic metal structure (e.g., the monolithic metal structure 106 in FIG. 1C) in the BEOL structure may be formed by different processes at different manufacturing steps (e.g., process of FIG. 5 and process of FIG. 11) for the metal via (e.g., the metal via 106V in FIG. 1C) and the (lower) metal pattern (e.g., the first metal pattern 106L in FIG. 1C) and therefore reduce the aspect ratio for forming the monolithic metal structure (specifically, the (lower) metal pattern). For example, the methods described herein may be referred to as metal via first scheme (or metal pattern last scheme).

The height variation (deviation) (in the first direction) of the metal patterns may be easily controlled (improved) by the metal via embedded hard mask (e.g., the second mask pattern 1026 in FIG. 10) because the patterning process of the metal patterns may be controlled by the etch selectivity with respect to an etch stop layer (e.g., the first etch stop layer 410 in FIG. 10), not by, for example, solely a time controlling. Also, the height variation (deviation) of the metal patterns may be controlled (improved) as the patterning process of the metal patterns may be performed through the metal via embedded hard masks because the densely arranged metal via embedded hard masks work similar to a planar surface together.

Also, the metal via revealing process may be easily controlled (referring to FIG. 14) because the metal via embedded hard masks (e.g., the second mask pattern 1026 in FIG. 10), which are densely and uniformly arranged (more densely and more uniformly arranged than the metal vias), may function as a CMP stop layer.

Example embodiments described herein may improve the electrical features, such as reliability, and the manufacturing yield of integrated circuit devices by controlling (improving) the uniformity of the conductive elements (e.g., the metal via and the metal pattern) in the BEOL structure.

Example embodiments are described herein with reference to the accompanying drawings. Many different forms and embodiments are possible without deviating from the spirit and teachings of this disclosure and so the disclosure should not be construed as limited to the example embodiments set forth herein. Rather, these example embodiments are provided so that this disclosure will be thorough and complete and will convey the scope of the disclosure to those skilled in the art. In the drawings, the sizes and relative sizes of layers and regions may be exaggerated for clarity. Like reference numbers refer to like elements throughout.

Example embodiments of the present inventive concept are described herein with reference to cross-sectional views or plan views that are schematic illustrations of idealized embodiments and intermediate structures of example embodiments. As such, variations from the shapes of the illustrations as a result, for example, of manufacturing techniques and/or tolerances, are to be expected. Thus, example embodiments of the present inventive concept should not be construed as limited to the particular shapes illustrated herein but include deviations in shapes that result, for example, from manufacturing.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the present inventive concept. As used herein, the singular forms “a,” “an” and “the” are intended to include the plural forms as well, unless the context clearly indicates otherwise. It will be further understood that the terms “comprises,” “comprising,” “includes” and/or “including,” when used in this specification, specify the presence of the stated features, steps, operations, elements and/or components, but do not preclude the presence or addition of one or more other features, steps, operations, elements, components and/or groups thereof. As used herein the term “and/or” includes any and all combinations of one or more of the associated listed items.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein, the term “and/or” includes any and all combinations of one or more of the associated listed items. Moreover, the symbol “/” (e.g., when used in the term “source/drain”) will be understood to be equivalent to the term “and/or.”

It will be understood that although the terms “first,” “second,” etc. may be used herein to describe various elements, these elements should not be limited by these terms. These terms are only used to distinguish one element from another. Thus, a first element could be termed a second element without departing from the teachings of the present embodiments.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

It should be noted that in some alternate implementations, the functions/acts noted in flowchart blocks herein may occur out of the order noted in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Finally, other blocks may be added/inserted between the blocks that are illustrated, and/or blocks/operations may be omitted without departing from the scope of the present inventive concept.

The above-disclosed subject matter is to be considered illustrative, and not restrictive, and the appended claims are intended to cover all such modifications, enhancements, and other embodiments, which fall within the true spirit and scope of the inventive concept. Thus, to the maximum extent allowed by law, the scope is to be determined by the broadest permissible interpretation of the following claims and their equivalents, and shall not be restricted or limited by the foregoing detailed description.

What is claimed is:

1. An integrated circuit device comprising:
a substrate;
a metal via on the substrate;
a metal pattern between the metal via and the substrate in a first direction that is perpendicular to an upper surface of the substrate;
a first insulating pattern that overlaps the metal pattern and the metal via in a second direction, wherein the second direction is parallel with the upper surface of the substrate; and
a second insulating pattern that overlaps the metal via in the second direction and overlaps the metal pattern in the first direction.

2. The integrated circuit device of claim 1, wherein the metal pattern and the metal via include a same material.

3. The integrated circuit device of claim 2, wherein the metal pattern and the metal via are integrated as a monolithic metal structure.

4. The integrated circuit device of claim 3, wherein a side surface of the metal via and a side surface of the metal pattern are non-coplanar with each other.

5. The integrated circuit device of claim 4, wherein the monolithic metal structure includes a step profile between the metal via and the metal pattern in the first direction.

6. The integrated circuit device of claim 5, wherein an upper surface of the metal pattern has a first width in the second direction and a second width in a third direction that is parallel with the upper surface of the substrate and intersects the second direction,
wherein a lower surface of the metal via has a third width in the second direction and a fourth width in the third direction, and
wherein the first width is greater than the third width, and the second width is greater than the fourth width.

7. The integrated circuit device of claim 6, wherein the step profile is at the upper surface of the metal pattern and the lower surface of the metal via, and
wherein the upper surface of the metal pattern is in contact with the lower surface of the metal via.

8. The integrated circuit device of claim 6, further comprising: an etch stop pattern between the metal via and the metal pattern in the first direction.

9. The integrated circuit device of claim 3, wherein a side surface of the metal pattern has a first slope with respect to the first direction,
wherein a side surface of the metal via has a second slope with respect to the first direction, and
wherein the second slope is different from the first slope.

10. The integrated circuit device of claim 1, wherein the first insulating pattern comprises an air gap that overlaps the metal pattern and the metal via in the second direction.

11. An integrated circuit device comprising:
a substrate;
monolithic metal structures that comprise metal vias on the substrate and metal patterns between the metal vias and the substrate in a first direction that is perpendicular to an upper surface of the substrate;
first insulating patterns that extend around the metal patterns and the metal vias; and
second insulating patterns that extend around the metal vias,
wherein the second insulating patterns overlap the metal patterns in the first direction.

12. The integrated circuit device of claim 11, wherein a side surface of at least one of the metal vias is non-coplanar with a side surface of a corresponding one of the metal patterns.

13. The integrated circuit device of claim 12 further comprising: a first air gap between adjacent ones of the second insulating patterns in a second direction that is parallel with the upper surface of the substrate, and
wherein the first air gap is between adjacent ones of the metal patterns in the second direction.

14. The integrated circuit device of claim 13, wherein at least one of the second insulating patterns includes a second air gap.

15. The integrated circuit device of claim 11, wherein a width in a second direction of an upper surface of at least one of the second insulating patterns is greater than a width in the second direction of a lower surface of the at least one of the second insulating patterns, and
wherein the second direction is parallel with the upper surface of the substrate.

16. A method of forming an integrated circuit device, the method comprising:
forming a stack structure that comprises a first etch stop layer, a metal layer, a second etch stop layer, and a first mask layer on a substrate;
forming a first mask pattern and a second etch stop pattern by patterning the first mask layer and the second etch stop layer, respectively;
forming a metal via by removing a portion of the metal layer through the first mask pattern and the second etch stop pattern;
removing the first mask pattern;
forming a second mask layer on the metal via;
forming a third mask pattern on the second mask layer, wherein the third mask pattern overlaps the metal via in a first direction that is perpendicular to an upper surface of the substrate;
forming a second mask pattern by removing a portion of the second mask layer through the third mask pattern; and
forming a metal pattern by removing a portion of the metal layer through the second mask pattern,
wherein a side surface of the metal pattern is non-coplanar with a side surface of the metal via.

17. The method of claim 16, further comprising:
forming a first insulating pattern that overlaps the metal pattern and the metal via in a second direction that is parallel with the upper surface of the substrate;
removing the second etch stop pattern; and
replacing the second mask pattern with a second insulating pattern that overlaps the metal via in the second direction,
wherein the second insulating pattern overlaps the metal pattern in the first direction, and
wherein the second insulating pattern is different from the first insulating pattern.

18. The method of claim 17, wherein the metal via is integrated with the metal pattern as a monolithic metal structure.

19. The method of claim 18, wherein the monolithic metal structure includes Ruthenium.

20. The method of claim 19, wherein the first insulating pattern includes an air gap that overlaps the metal pattern and the metal via in the second direction.
